(19) United States
(12) Patent Application Publication
(10) Pub. No.: US 2012/0286889 A1
(43) Pub. Date: Nov. 15, 2012

(54) Systems and Methods for Wideband CMOS Voltage-Controlled Oscillators Using Reconfigurable Inductor Arrays

(75) Inventors: Yunseo Park, Norcross, GA (US); Jaejoon Kim, Seoul (KR); Chang-Ho Lee, Marietta, GA (US)

(73) Assignee: SAMSUNG ELECTRO-MECHANICS COMPANY, Gyunggi-Do (KR)

(21) Appl. No.: 13/104,807

(22) Filed: May 10, 2011

(51) Int. Cl. H03B 5/12

(52) U.S. Cl. 331/117 FE

(57) ABSTRACT

As wireless communication technology evolves, various transceivers become integrated into a single system, which implements a seamless connection to search available frequency bands and to provide wireless connections regardless of their wireless standards. One of the key technologies for seamless implementation is an ultra-wideband local oscillator, which can overcome the restriction of limited tuning range in typical RF local oscillators. Many RF oscillators incorporate LC-tuned oscillators because of their good noise performance while their tuning range is limited by fixed inductance and varied capacitance. The planar inductor fabricated on the CMOS process occupies a large area as well. By replacing the planar inductor with the array of bondwires, and including switches to provide proper impedance for the circuit to generate negative impedance, the tuning range of a CMOS voltage-controlled oscillator (VCO) is extended more than 100%, which number can not be achieved in a convention VCO.

### FIELD OF INVENTION

Embodiments of the invention relate generally to complementary metal oxide semiconductor (CMOS) voltage-controlled oscillators, and more particularly, to CMOS voltage-controlled oscillators using reconfigurable inductor arrays.

### BACKGROUND OF THE INVENTION

Recent technology trends such as seamless wireless connectivity and cognitive radios require the use of an ultra-wideband radio frequency (RF) voltage-controlled oscillator (VCO). Previously, several LC-tuned oscillators had to be integrated together to cover various frequency bands, thereby resulting in area inefficiency because of the need to integrate many spiral inductors. In limited circumstances, inherent wideband oscillators, such as ring oscillators and relaxation oscillators, have been used reduce the area, but only when their signal-purity requirement is not stringent.

Accordingly, there is an opportunity for systems and methods for wideband CMOS voltage-controlled oscillators using reconfigurable inductor arrays.

BRIEF SUMMARY OF THE INVENTION

Some or all of the above needs and/or problems may be addressed by certain embodiments of the invention.

According to an example embodiment of the invention, there is a reconfigurable network for a voltage-controlled oscillator. The reconfigurable network may include a plurality of capacitors, where a respective capacitance of at least a portion of the plurality of capacitors is adjustable, where the plurality of capacitors are connected between a first port and a second port; a plurality of inductors; and a plurality of switches for selecting one or more of the plurality of inductors, where the selected ones of the inductors are connected between the first port and the second port based upon the configuration of the plurality of switches, where the plurality of capacitors, inductors, and switches collectively form a resonance LC tank circuit having the first port and the second port.

According to another example embodiment, there is a method. The method may include providing a plurality of capacitors, where a respective capacitance of at least a portion of the plurality of capacitors is adjustable, where the plurality of capacitors are connected between a first port and a second port; providing a plurality of inductors; and configuring a plurality of switches for selecting one or more of the plurality of inductors, where the selected ones of the inductors are connected between the first port and the second port based upon the configuration of the plurality of switches, where the plurality of capacitors, inductors, and switches collectively form a resonance LC tank circuit having the first port and the second port.

### BRIEF DESCRIPTION OF THE DRAWINGS

Having thus described the invention in general terms, reference will now be made to the accompanying drawings, which are not necessarily drawn to scale, and wherein:

FIG. 1A illustrates an example schematic of a VCO in accordance with an example embodiment of the invention.

FIG. 1B illustrates an example LC tank circuit that utilizes reconfigurable inductor arrays and varactor arrays, according to an example embodiment of the invention.

FIGS. 2A-2C provide respective schematic diagrams of series-connected tunable inductor arrays, parallel-connected tunable inductor arrays, and reconfigurable tunable inductor arrays, respectively, according to an example embodiment of the invention.

FIG. 3 is a schematic diagram of a VCO with series-connected tunable inductor arrays and varactor arrays, according to an example embodiment of the invention.

FIG. 4 illustrates the measured tuning range of a sample of an example VCO over a control voltage, according to an example embodiment of the invention.

FIG. 5 is an example illustration of a sample die of an example VCO fabricated on a CMOS process, according to an example embodiment of the invention.

FIG. 6 illustrates the measured phase noise of a sample of a VCO at high-end tuning frequency, according to an example embodiment of the invention.

### DETAILED DESCRIPTION OF THE INVENTION

Example embodiments of the invention now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

As wireless communication technology evolves, various transceivers become integrated into a single system in order to provide a seamless connection to search for available frequency bands and to provide wireless connections across various wireless standards and protocols. One of the limitations for the seamless implementation is the local oscillator, which conventionally has a limited tuning range. Indeed, many RF oscillators incorporate LC-tuned oscillators because of their good noise performance but their tuning range is limited by fixed inductance and varied capacitance. The planar inductor fabricated on the CMOS process occupies a large area as well.

Embodiments of the invention may provide for a wideband CMOS voltage-controlled oscillator, which can overcome the limited tuning range of conventional RF local oscillators. Indeed, by utilizing an array of bondwires or bonding inductors that are selectable using switches, a desired impedance can be obtained for an LC tank circuit to generate negative impedance. Accordingly, the tuning range of the example CMOS VCO may be extended more than 100%, which cannot be achieved in a conventional VCO. Likewise, the example CMOS VCO may have good phase noise characteristics, according to an example embodiment of the invention.

Example embodiments of the invention may provide for an example ultra-wideband CMOS voltage-controlled oscillator (VCO) with reconfigurable inductor arrays. As described in further detail herein, the example VCO with reconfigurable inductor arrays may be comprised of active transconductance cells to generate negative transconductance (gm), reconfigurable bonding inductors array with one or more switch controls, and a varactor (e.g., variable capacitor) array with one or more switch controls, according to an example embodiment of the invention.

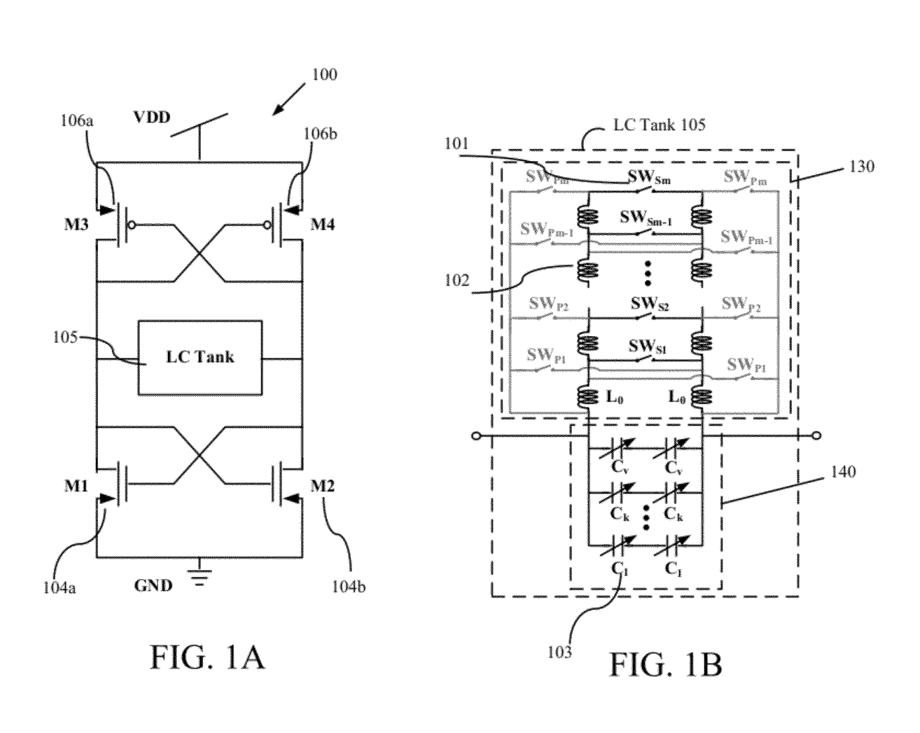

FIG. 1A illustrates an example CMOS voltage-controlled oscillator (VCO) 100 in accordance with an example embodiment of the invention. As shown in FIG. 1, the example VCO can include n-channel metal-oxide-semiconductor (NMOS) transistors 104a (M1), 104b (M2) and p-channel metal-oxide-semiconductor (PMOS) transistors 106a (M3), 106b (M4). NMOS transistors 104a (M1), 104b (M2) may be cross-coupled such that the gate of transistor 104a (M1) is connected to the drain of transistor 104b (M2), and the gate of transistor 104b (M2) is connected to the drain of transistor 104a (M1). Similarly, PMOS transistors 106a (M3), 106b (M4) may be cross-coupled such that the gate of transistor 106a (M3) is connected to the drain of transistor 106b (M4), and the gate of transistor 106b (M4) is connected to the drain of transistor 106a (M3). To provide a complementary configuration, the drain of NMOS transistor 104a (M1) (also coupled to the gate of transistor 104b) may be connected to the drain of PMOS transistor 106a (M3) (also coupled to the gate of transistor 106b), while the drain of NMOS transistor 104b (M2) (also coupled to the gate of transistor 104a) may be connected to the drain of PMOS transistor 106b (M4) (also coupled to the gate of transistor 106a). The sources of NMOS transistors 104a (M1), 104b (M2) may be connected to ground (GND), while the sources of PMOS transistors 106a (M3), 106b (M4) may be connected to DC supply voltage VDD.

In addition, FIG. 1A illustrates a resonant (or resonator) network comprising an LC tank 105 that is in electrical connection with transistors 104a, 104b, 106a, and 106b. In particular, a first port of the LC tank 105 may be connected to a first node connecting the drains of transistors 104a, 106a, and the gates of transistors 104b, 106b. A second port of the LC tank 105 may be connected to a second node connecting the drains of transistors 104b, 106b, and the gates of transistors 104a, 106a. As will be described in further detail herein, the LC tank 105 may include one or both of reconfigurable inductor arrays and varactor arrays.

In FIG. 1A, the transistors 104a (M1), 104b (M2), 106a (M3), 106b (M4) may generate sufficient transconductance (gm) to provide negative resistance to compensate for the resistive loss of the resonant network (e.g., LC tank 105). For example, the negative resistance from FIG. 1A can be approximated as −4/gm due to the complementary topology of the structure, where gm is a transconductance of each transistor 104a, 104b, 106a, 106b.

More specifically, the transistors 104a (M1), 104b (M2), 106a (M3), 106b (M4) may be referred to as active transconductance cells. The active transconductance cells of the example VCO 100 may generate negative transconductance (gm) that is utilized to provide negative resistance to a resonator network such as the LC tank 105. Indeed, the transconductance (gm) of the example VCO 100 may be directly related to the negative resistance. When the negative resistance is more than total resistance, which is mainly caused from the resistive loss of the resonator network (e.g., LC tank 105), a circuit builds up a signal from its noise and sustains the signal shaped by the characteristics of the resonator network.

The total resistance that is mainly from resistive loss of a resonator network (e.g., LC tank 105) may be related to quality factor (Q) of the resonator network and its series resistive loss term (Rs). The total resistance (Rp) of the resonator network can be described roughly at the center of the resonance frequency as in Equation (1) below:

Rₚ=Q²Rₛ (1)

Oscillation typically starts and is sustained when the transconductance (gm) is >−4/Rp, which means that the required transconductance (gm) for oscillation is related to the total resistance.

In an LC oscillator, the resonance frequency and total resistance (Rp) of a resonator may be restricted by the tuning range of a varactor because the inductance is usually fixed. However, by providing reconfigurable inductor arrays for the example resonator network (e.g., LC tank 105), the tuning range of an LC oscillator can be extended beyond the tuning range of a varactor. When combined inductor arrays and varactor arrays are utilized for the example resonator network (e.g., LC tank 105), the tuning range of the VCO 100 can be extended further.

In an example embodiment of the invention, the use of bonding inductors in the inductor array for the example resonator network (e.g., LC tank 105) may achieve a high total resistance (Rp) because of (i) a high quality factor (Q) associated with the bonding inductors, which leads to low power consumption in generating necessary transconductance (gm) to start an oscillation, and (ii) much less area to achieve the same tuning range of the VCO 100 when compared with the case of using multiple planar inductors because of low parasitic capacitance associated with it and the vertical nature of the bonding inductors. It will be appreciated that the use of bonding inductors in a VCO 100 is typically not recommended because the frequency of the VCO is highly susceptible to the bonding inductance variation due to the high quality factor of the inductor. However, embodiments of the invention can overcome this problem by providing a large tuning range that can compensate for bonding inductance variation of the bonding inductors.

It will be appreciated that many variations of the example VCO 100 are available in accordance with example embodiments of the invention. Indeed, any VCO topology that utilizes differential signals may be utilized for implementing the example VCO 100, according to an example embodiment of the invention.

FIG. 1B illustrates an example implementation for the example LC tank 105 of FIG. 1A. As shown in FIG. 1B, the example LC tank 105 may include a reconfigurable inductor array 130 and a varactor array 140. The reconfigurable inductor array 130 can include a plurality of inductors 102 as well as a plurality of switches. The inductors 102 can be bonding inductors or bondwire inductors, according to an example embodiment of the invention. The plurality of switches can include one or both of series switches SWₛ₁₋ₘ or parallel switches SW_{P1-m}. In general, one or more series switches SWₛ₁₋ₘ can be used to connect one or more inductors 102 in series between the first and second differential ports of the LC tank 105. On the other hand, one or more parallel switches SW_{P1-m} can be used to connect one or more inductors 102 in parallel between the first and second differential ports of the LC tank 105, according to an example embodiment of the invention. It will be appreciated that in order to improve the quality factor of the reconfigurable tunable inductor array 130, switches for the series connection and the parallel connection may be separately implemented as switches SW_{S1}-SW_{Sm} and switches SW_{P1}-SW_{Pm}, respectively. In an example, embodiment of the invention, the inductors 102 can each have an inductance of substantially L₀. However, in other embodiments, each differential pair may have substantially the same inductance, and the inductance may vary from differential pair to differential pair, according to an example embodiment of the invention.

For the series-connection mode, the parallel switches SW_{P1-m} may be opened (OFF) while one or more series switches SW_{S1}-SW_{Sm} may be closed (ON). When switch SWₖ is on, then the equivalent series inductance may be the value of k*L₀ for the inductor array 130, where k is the number of inductor pairs in series and L₀ may be the inductance of each inductor in series. On the other hand, for a parallel-connection mode, the series switches SW_{S1}-SW_{Sm} may be opened (OFF) while one or more parallel switches may be closed (ON). It will be appreciated that closing both parallel switches SW_{P1} may yield the equivalent inductance of L₀/4 while closing switch SW_{P1} through switch SW_{Pk} yields the equivalent inductance of L₀/[2(k+1)] for the inductor array 130. In order for the inductor array to yield an equivalent inductance of L₀/2, only one switch among first differential switch pair (SW_{P1}) can be turned on, according to an example embodiment of the invention. Accordingly, by opening or closing various combinations of series switches SWₛ₁₋ₘ or parallel, various combinations of inductors 102 can be placed in series and/or parallel in order to reconfigure the array 130 to provide a desired inductance for frequency tuning in accordance with an example embodiment of the invention.

Still referring to FIG. 1B, the varactor array 140 can include a plurality of variable capacitor (e.g., varactor) pairs C₁-Cₖ and Cᵥ. In an example embodiment of the invention, variable capacitor pairs C₁-Cₖ may be utilized to adjust the capacitance for coarse frequency tuning On the other hand, variable capacitor pairs C₁-Cₖ can be utilized to more finely adjust the capacitance for fine frequency tuning, according to an example embodiment of the invention. In general, coarse frequency tuning typically occurs during a first step to adjust the capacitance in larger increments, thereby adjusting the frequency in large increments. Typically, when the current frequency is within a range of the desired frequency, then coarse frequency tuning may be utilized to adjust the capacitance in smaller increments, thereby adjusting the frequency in small increments.

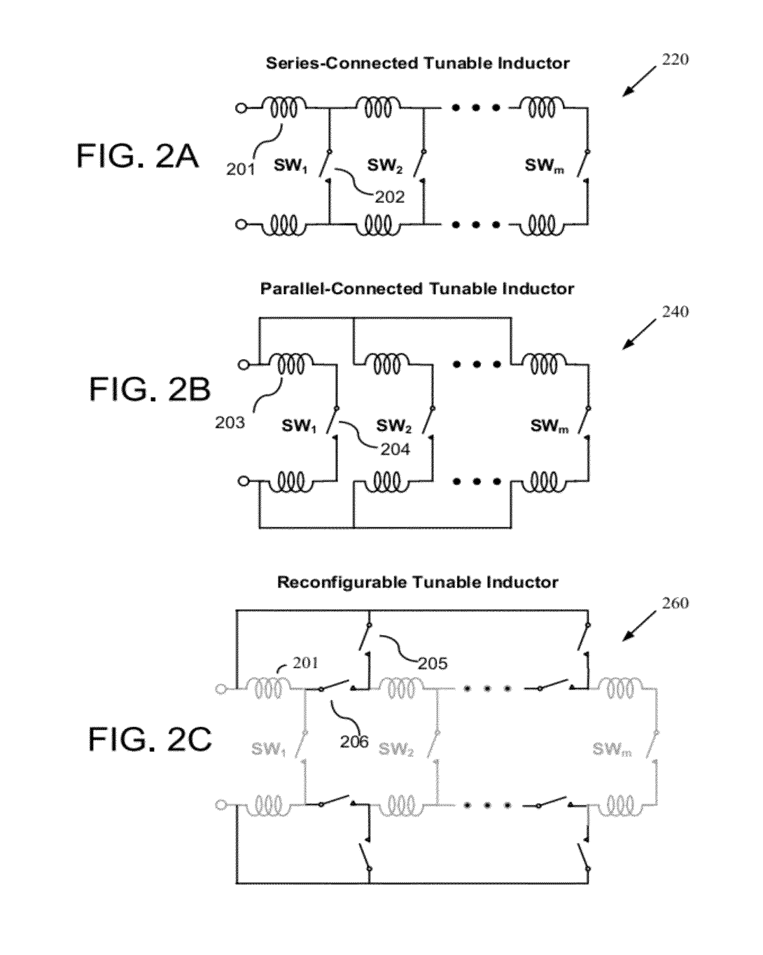

FIG. 2A illustrates an example configuration for a series-connected tunable inductor array 220. In FIG. 2A, the series-connected tunable inductor array 220 can include a plurality of inductors 201 that can be connected in series between a first and second port (of the resonant circuit) based upon switches 201 (SW₁₋ₘ). For example, if the second switch SW₂ is closed, then there may be two inductors 201 configured in series for each differential path. The series-connected structure of the tunable inductors provides area-efficient inductance tenability by utilizing bondwires as unit inductors, and may also have an advantage of minimizing the effect of quality-factor degradation due to switch on-resistance by sharing only one switch SW₁₋ₘ between differential inductors 201.

The series-connected tunable inductor array 220 of FIG. 2A can be modified to yield the example parallel-connected tunable inductor array 240. In particular, in FIG. 2B, the parallel-connected tunable inductor array 240 may include a plurality of inductors 203 that can be connected in parallel between a first and second port (of the resonant circuit) based upon switches 204 (SW₁₋ₘ). For example, if the first and second switches SW₁, SW₂ are closed, then there may be two inductors configured in parallel for each parallel path. The parallel-connected tunable inductor array 240 may be more suitable for generating smaller inductance values that are beneficial to achieving a high frequency oscillation.

It will be appreciated that a difference between the series-connected tunable inductor array 220 and the parallel-connected tunable inductor array 240 may be the control or programming method. In particular, in the series-connected tunable inductor array 220, only one switch may be closed or turned on to connect k inductor pairs in series, whereas in the parallel-connected tunable inductor array 240, every switch from SW₁ to SWₖ may be closed or turned on to connect k inductor pairs in parallel. It will be appreciated that the series-connected tunable inductor array 220 and/or the parallel-connected tunable inductor array 240 can be utilized as an alternative implementation of the reconfigurable inductor array 130 of the example LC tank 105 of FIGS. 1A and 1B.

FIG. 2C illustrates reconfigurable tunable inductor array 260 that can support both the series and the parallel structure. In particular, the reconfigurable tunable inductor array 260 may be similar to the series-connected tunable inductor array 220 based upon inductors 201 and switches 201 (SW₁₋ₘ). However, the reconfigurable tunable inductor array 260 further provides switches 205 and 206 in order to allow the inductors 201 to be connected in both series and parallel between a first and second port (of the resonant circuit). As an example, switches 206 can be used to connect one or more combinations of inductors in series. Switches 205 can be used to create additional parallel combinations of inductors. By configuring switches 201, 205, 206, the inductors can be series, parallel, or combined series and parallel configurations. Accordingly, with the same number of inductors 201, the reconfigurable tunable inductor array 260 can make the tuning range of equivalent inductance two times wider.

It will be appreciated that when a reconfigurable tunable inductor array (e.g., array 220, 240, or 260) is utilized with an inductor array (e.g., array 140), the necessary impedance can be provided to the oscillator core such that the transconductance (gm) of the VCO is low enough to reduce current consumption, according to an example embodiment of the invention.

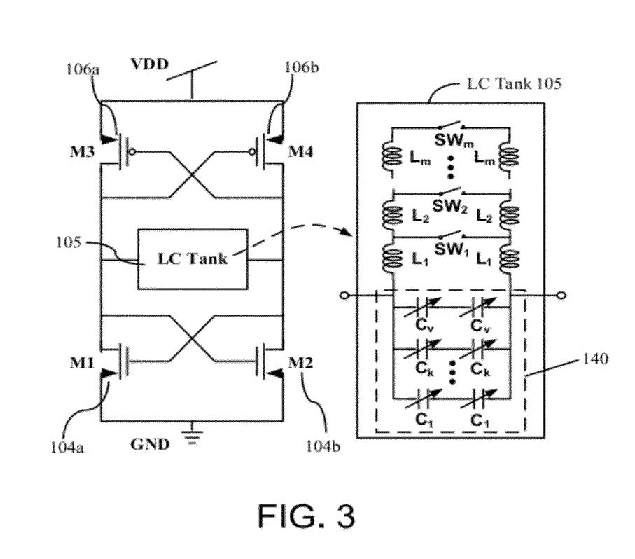

FIG. 3 illustrates a variation of the example CMOS voltage-controlled oscillator (VCO) 100 of FIG. 1A. In particular, as shown in FIG. 3, the example LC tank 105 may be implemented using the series-connected tunable inductor array similar to that described with respect to FIG. 2A. It will be appreciated that many variations of the example LC tank 105 are available without departing from example embodiments of the invention.

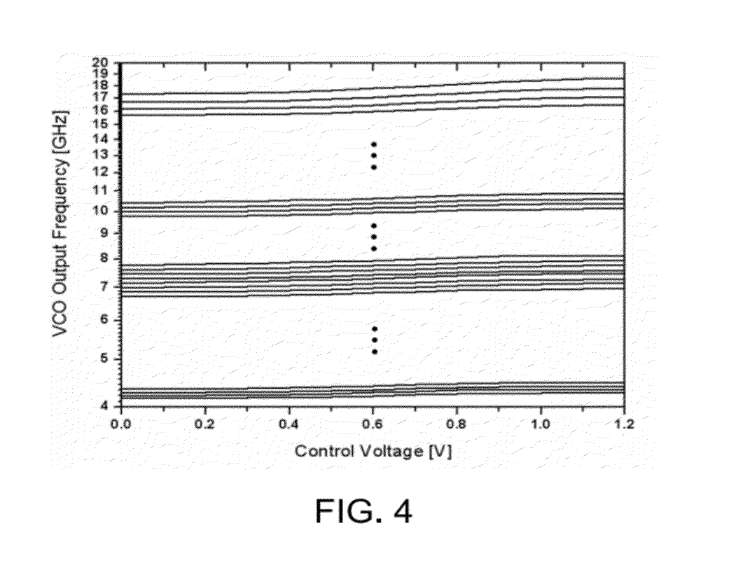

FIG. 4 illustrates the measured VCO output frequency over an applied control voltage. Discrete inductor switching in an inductor array and coarse capacitor tuning in a varactor array may provide discrete frequency outputs, while varactors in the varactor array can provide continuous tuning range between each of its discrete frequency output, thereby covering the entire frequency tuning range.

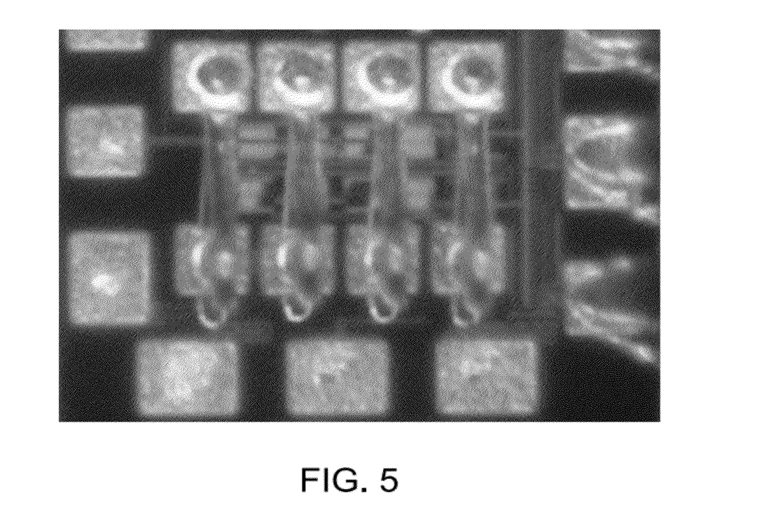

FIG. 5 illustrates die photo of an example VCO fabricated on a CMOS process demonstrating aggressive size reduction compared to conventional design. In FIG. 5, the example inductors are shown as being implemented using bonding inductors.

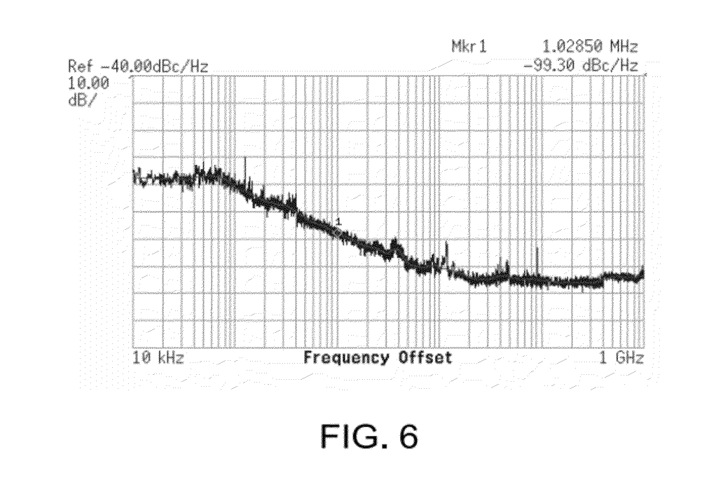

FIG. 6 illustrates the measured phase noise of a sample of a VCO at high-end tuning frequency, according to an example embodiment of the invention. In particular, FIG. 6 illustrates good phase noise performance of the example VCO by showing the phase noise at 12.7 GHz oscillation frequency, according to an example embodiment of the invention.

Many modifications and other embodiments of the invention set forth herein will come to mind to one skilled in the art to which these inventions pertain having the benefit of the teachings presented in the foregoing descriptions and the associated drawings. Therefore, it is to be understood that the inventions are not limited to the specific embodiments disclosed and that modifications and other embodiments are intended to be included within the scope of the appended claims. Although specific terms are employed herein, they are used in a generic and descriptive sense only and not for purposes of limitation.

1. A reconfigurable network for a voltage-controlled oscillator, comprising:
a plurality of capacitors, wherein a respective capacitance of at least a portion of the plurality of capacitors is adjustable, wherein the plurality of capacitors are connected between a first port and a second port;
a plurality of inductors; and
a plurality of switches for selecting one or more of the plurality of inductors, wherein the selected ones of the inductors are connected between the first port and the second port based upon the configuration of the plurality of switches,
wherein the plurality of capacitors, inductors, and switches collectively form a resonance LC tank circuit having the first port and the second port.

2. The reconfigurable network of claim 1, wherein at least one of the plurality of switches is closed to connect the selected inductors between the first port and the second port.

3. The reconfigurable network of claim 1, wherein the plurality of inductors comprise bonding inductors.

4. The reconfigurable network of claim 3, wherein a sensitivity of oscillation frequency based upon variations of the bonding inductor is compensated for based upon a turning range provided by the adjustable capacitors and selections of the inductors connected between the first port and the second port.

5. The reconfigurable network of claim 1, wherein at least a portion of the capacitors are respective varactors.

6. The reconfigurable network of claim 1, wherein the first port and the second port of the LC tank circuit are connected to a plurality of transistors to form an oscillator.

7. The reconfigurable network of claim 6, wherein the plurality of transistors operate as active transconductance cells to provide negative resistance to the LC tank circuit.

8. The reconfigurable network of claim 6, wherein an amount of the provided negative resistance is based upon respective transconductance of the active transconductance cells.

9. The reconfigurable network of claim 6, wherein the negative resistance compensates for resistive loss from the LC tank circuit.

10. The reconfigurable network of claim 6, wherein a tuning range of the oscillator is a wideband without substantial degradation of a performance factor of the oscillator across the wideband tuning range.

11. The reconfigurable network of claim 6, wherein the LC tank circuit provides large total resistance based in part on the inductors and capacitors, thereby reducing transconductance requirements of the oscillator and associated current consumption by the transistors.

12. A method, comprising:
providing a plurality of capacitors, wherein a respective capacitance of at least a portion of the plurality of capacitors is adjustable, wherein the plurality of capacitors are connected between a first port and a second port;
providing a plurality of inductors; and
configuring a plurality of switches for selecting one or more of the plurality of inductors, wherein the selected ones of the inductors are connected between the first port and the second port based upon the configuration of the plurality of switches,
wherein the plurality of capacitors, inductors, and switches collectively form a resonance LC tank circuit having the first port and the second port.

13. The method of claim 12, wherein at least one of the plurality of switches is closed to connect the selected inductors between the first port and the second port.

14. The method of claim 12, wherein the plurality of inductors comprise bonding inductors.

15. The method of claim 14, wherein a sensitivity of oscillation frequency based upon variations of the bonding inductor is compensated for based upon a turning range provided by the adjustable capacitors and selections of the inductors connected between the first port and the second port.

16. The method of claim 12, wherein at least a portion of the capacitors are respective varactors.

17. The method of claim 12, wherein the first port and the second port of the LC tank circuit are connected to a plurality of transistors to form an oscillator.

18. The method of claim 17, wherein the plurality of transistors operate as active transconductance cells to provide negative resistance to the LC tank circuit.

19. The method of claim 17, wherein an amount of the provided negative resistance is based upon respective transconductance of the active transconductance cells.

20. The method of claim 17, wherein the negative resistance compensates for resistive loss from the LC tank circuit.
